(19) United States
(12) Patent Application Publication
(10) Pub. No.: US 2003/0085452 A1
(43) Pub. Date: May 8, 2003

(54) Packaging architecture for a multiple array transceiver using a continuous flexible circuit

(75) Inventors: Johnny R. Brezina, Austin, TX (US); Christopher M. Gabel, Rochester, MN (US); Eric P. Heussi, Cedar Park, TX (US); Brian M. Kerrigan, Austin, TX (US); Gerald D. Malagrino JR., Rochester, MN (US); James R. Moon, Oronoco, MN (US)

Correspondence Address: Intellectual Property Law Dept., IBM Corporation, 11400 Burnet Road, Zip 4054, Austin, TX, 78758, US

(73) Assignee: International Business Machines Corporation, Armonk, NY

(21) Appl. No.: 10/007,026

(22) Filed: Nov. 5, 2001

(51) Int. Cl. H01L 23/495

(52) U.S. Cl. 257/666

(57) ABSTRACT

The packaging architecture for a multiple array transceiver using a continuous flexible circuit of the present invention provides a 90-degree transition between an optical signal input at a communications chassis bulkhead and an interior board within the communications chassis. In one form, the multiple array transceiver comprises a forward vertical carrier having an optical converter, such as a laser or a photodetector, a rearward horizontal block oriented about 90 degrees from the forward vertical carrier, and a flexible circuit having a plurality of electrical layers between the forward vertical carrier and the rearward horizontal block. The flexible circuit can have a power layer, a ground layer, and a signal layer. The multiple array transceiver can further provide a heat sink, a ground land and a power land on the vertical carrier face, and a lens housing assembly aligning an optical lens array with the optical converter.

### RELATED APPLICATIONS

This application claims priority to U.S. patent application Ser. No. 09/956,771 filed on Sep. 20, 2001 entitled “Fiber Optic Transceiver, Connector, And Method of Dissipating Heat” by Johnny R. Brezina, et al., the entire disclosure of which is incorporated by reference, herein.

This application also relates to the following applications, filed concurrently herewith:

“Optical Alignment In A Fiber Optic Transceiver”, by Johnny R. Brezina, et al. (IBM Docket No. AUS920010689US1);

“External EMI Shield For Multiple Array Optoelectronic Devices”, by Johnny R. Brezina, et al. (IBM Docket No. AUS920010690US1);

“Flexible Cable Stiffener for An Optical Transceiver”, by Johnny R. Brezina, et al. (IBM Docket No. AUS920010729US1);

“Enhanced Folded Flexible Cable Packaging for Use in Optical Transceivers, by Johnny R. Brezina, et al. (IBM Docket No. AUS920010727US1);

“Apparatus and Method for Controlling an Optical Transceiver”, by Johnny R. Brezina, et al. (IBM Docket No. AUS920010728US1);

“Internal EMI Shield for Multiple Array Optoelectronic Devices”, by Johnny R. Brezina, et al. (IBM Docket No. AUS920010730US1);

“Multiple Array Optoelectronic Connector with Integrated Latch”, by Johnny R. Brezina, et al. (IBM Docket No. AUS920010731US1);

“Mounting a Lens Array in a Fiber Optic Transceiver”, by Johnny R. Brezina, et al. (IBM Docket No. AUS920010733US1);

“Packaging Architecture for a Multiple Array Transceiver Using a Flexible Cable”, by Johnny R. Brezina, et al. (IBM Docket No. AUS920010734US1);

“Packaging Architecture for a Multiple Array Transceiver Using a Flexible Cable and Stiffener for Customer Attachment”, by Johnny R. Brezina, et al. (IBM Docket No. AUS920010735US1);

“Packaging Architecture for a Multiple Array Transceiver Using a Winged Flexible Cable for Optimal Wiring”, by Johnny R. Brezina, et al. (IBM Docket No. AUS920010736US1); and

“Horizontal Carrier Assembly for Multiple Array Optoelectronic Devices”, by Johnny R. Brezina, et al. (IBM Docket No. AUS920010763US1).

### TECHNICAL FIELD

The technical field of this disclosure is computer systems, particularly, a packaging architecture for a multiple array transceiver using a continuous flexible circuit.

### BACKGROUND OF THE INVENTION

Optical signals entering a communications chassis can be converted to electrical signals for use within the communications chassis by a multiple array transceiver. The configuration of optical signal connections entering the communications chassis and the customer's circuit boards within the chassis require a 90-degree direction change in signal path from the optical to the electrical signal. This 90-degree configuration is required due to the right angle orientation between the customer's board and the rear bulkhead of the chassis. Existing multiple array transceiver designs use a number of small parts, such as tiny flexible interconnects with associated circuit cards and plastic stiffeners, to make the 90-degree transition. The size and number of the parts increases manufacturing complexity and expense.

In addition, existing multiple array transceivers are limited in the number of electrical signal paths they can provide between the optical input and the customer's board. It is desirable to provide as many electrical signal paths as possible, because optical fiber can typically provide a greater information flow rate than electrical wire. Industry and company standards further limit the space available for signal paths from the optical input to the customer's board, limiting the space to a narrow gap.

Thermal considerations may also limit the signal carrying capacity of current multiple array transceivers. Heat is generated by electrical resistance as the signals pass through the conductors and as the signals are processed by solid-state chips within the transceivers. Limitations on heat dissipation can limit the data processing speed and reduce transceiver reliability. Also, use of materials with different coefficients of thermal expansion can result in misalignment of optical components at different temperatures.

Problems also arise in maintaining signal strength and integrity. Long electrical paths between electronic components can increase line impedance and allow cross talk. Poor alignment between the multiple array transceiver and the external fiberoptic connector can result in loss of signal strength. Mounting optical components such as laser and photodetector chips on non-planar surfaces can cause chip tilt and light path straying.

It would be desirable to have a packaging architecture for a multiple array transceiver using a continuous flexible circuit that would overcome the above disadvantages.

### SUMMARY OF THE INVENTION

The packaging architecture for a multiple array transceiver using a continuous flexible circuit of the present invention provides a 90-degree transition between an optical signal input at a communications chassis bulkhead and an interior board within the communications chassis. In one form, the multiple array transceiver comprises a forward vertical carrier having an optical converter, such as a laser or a photodetector, a rearward horizontal block oriented about 90 degrees from the forward vertical carrier, and a flexible circuit having a plurality of electrical layers between the forward vertical carrier and the rearward horizontal block. The flexible circuit can have a power layer, a ground layer, and a signal layer. The multiple array transceiver can further provide a heat sink, a ground land and a power land on the vertical carrier face for attaching laser and photodetector dies, and a lens housing assembly aligning an optical lens array with the optical converter.

One aspect of the present invention provides a packaging architecture for a multiple array transceiver providing a 90-degree transition between the interior board and the rear bulkhead of the chassis.

Another aspect of the present invention provides a packaging architecture for a multiple array transceiver with a reduced number of components for manufacturing ease and reduced cost.

Another aspect of the present invention provides a packaging architecture for a multiple array transceiver providing an interconnection containing a very large number of signal paths in a narrow horizontal gap.

Another aspect of the present invention provides a packaging architecture for a multiple array transceiver providing a thermally efficient design with heat flow to a heat sink.

Another aspect of the present invention provides a packaging architecture for a multiple array transceiver providing use of materials with similar coefficients of thermal expansion to maintain optical component alignment at different operating temperatures.

Another aspect of the present invention provides a packaging architecture for a multiple array transceiver providing short electrical paths to limit line impedance and cross talk.

Another aspect of the present invention provides a packaging architecture for a multiple array transceiver providing high light energy coupling efficiency between the multiple array transceiver and the external fiberoptic connector.

Another aspect of the present invention provides a packaging architecture for a multiple array transceiver providing planar optical component mounting surfaces to reduce chip tilt and light path straying.

The foregoing and other features and advantages of the invention will become further apparent from the following detailed description of the presently preferred embodiments, read in conjunction with the accompanying drawings. The detailed description and drawings are merely illustrative of the invention, rather than limiting the scope of the invention being defined by the appended claims and equivalents thereof.

### BRIEF DESCRIPTION OF THE DRAWINGS

FIG. 1 shows an isometric diagram of a forward vertical carrier made in accordance with the present invention;

FIG. 2 shows a schematic diagram of a continuous flexible circuit made in accordance with the present invention;

FIGS. 3A & 3B show isometric diagrams of a packaging architecture for a multiple array transceiver using a continuous flexible circuit made in accordance with the present invention;

FIGS. 4A-4D show isometric diagrams of one embodiment of electrical connections for a forward vertical carrier made in accordance with the present invention;

FIGS. 5A & 5B show isometric diagrams of another embodiment of electrical connections for a forward vertical carrier made in accordance with the present invention; and

FIGS. 6A-6C show isometric diagrams of a multiple array transceiver lens assembly made in accordance with the present invention.

### DETAILED DESCRIPTION OF THE PRESENTLY PREFERRED EMBODIMENTS

The packaging architecture for a multiple array transceiver using a continuous flexible circuit of the present invention provides a 90-degree transition between an optical signal input at a communications chassis bulkhead and an interior board within the communications chassis. The multiple array transceiver makes the 90-degree transition within a narrow gap established by industry and manufacturer standards. The multiple array transceiver further provides cooling through a heat sink.

The present invention is shown and described by the following description and figures, and is generally described in the order in which the individual components are assembled during manufacture.

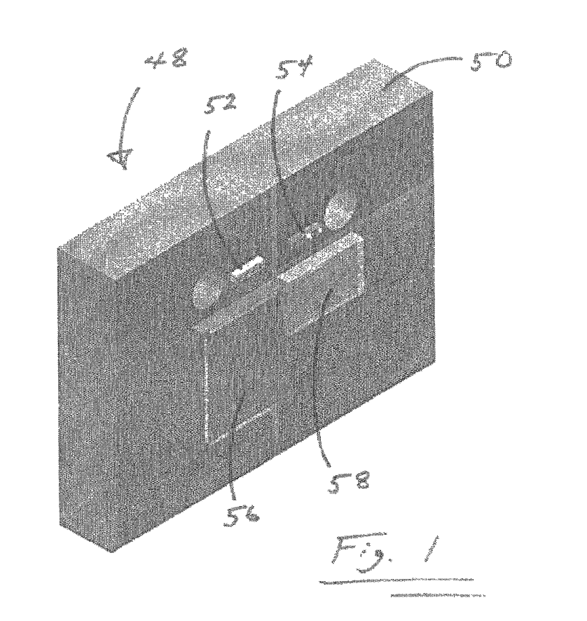

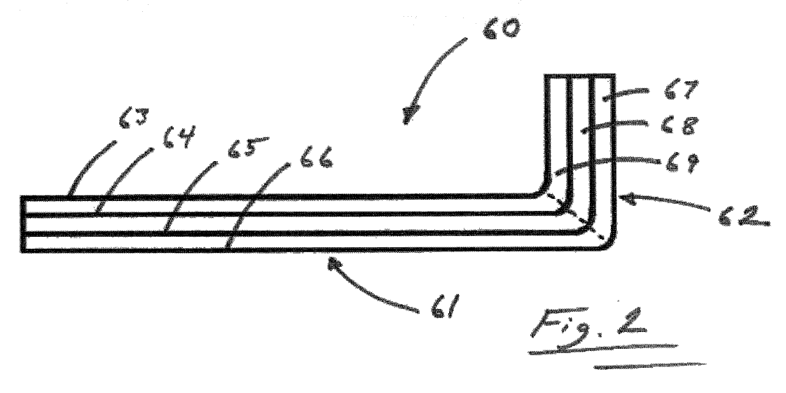

FIG. 1 shows an isometric diagram of a forward vertical carrier made in accordance with the present invention. The forward vertical carrier 48 comprises common substrate carrier 50, laser die 52, photodetector die 54, laser drive amplifier (LDA) 56, and transimpedance amplifier (TIA) 58. The common substrate carrier 50 can be made of a material with good thermal conductivity, such as copper, aluminum nitride, or the like. The common substrate carrier 50 can have a planar face to allow precise mounting of the optical components. The laser die 52 and photodetector die 54 are attached to a common substrate carrier 50 by using standard die bond epoxy material and technique as will be appreciated by those skilled in the art. The laser drive amplifier 56 (LDA) and transimpedance amplifier 58 (TIA) are also die bonded to the substrate carrier 50 in close proximity to the laser die 52 and photodetector die 54 to provide short critical transmission interconnection wire bond lengths. The TIA 58 acts as the photodetector interface chip. The laser die 52 and photodetector die 54 are precisely aligned to provide optimum communication with a fiber optic cable which can be attached to the laser die 52 and photodetector die 54. In other embodiments, some of the electronic components above can be omitted from forward vertical carrier 48, or additional or alternative electronic components can be included in the forward vertical carrier 48.

The laser die 52 and photodetector die 54 with their associated circuits perform as optical converters to convert an electrical signal from the transceiver to a light signal or convert a light signal coming into the transceiver to an electrical signal. In one embodiment, the optical converters can be lasers only, so that the transceiver only transmits optical signals. In another embodiment, the optical converters can be photodetectors only, so that the transceiver only receives optical signals. In other embodiments, the number of lasers and photodetectors can be predetermined to meet the number of transmit and receive channels desired.

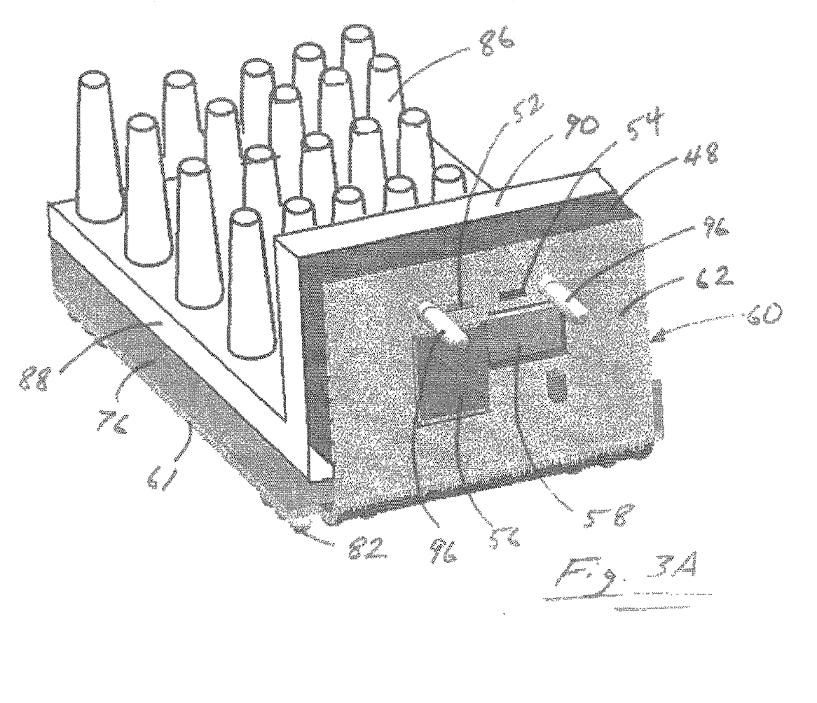

FIG. 2 shows a schematic diagram of a continuous flexible circuit made in accordance with the present invention.

A flexible circuit 60 comprises a first circuit portion 61 and a second circuit portion 62. In the assembled multiple array transceiver, the first circuit portion 61 can be generally horizontal and the second circuit portion 62 can be generally vertical, to meet the required 90 degree change in signal path direction. Thus, the first circuit portion 61 is oriented at about a 90-degree angle to the second circuit portion 62.

The flexible circuit 60 comprises three electrical layers and four insulating layers: power layer 69, ground layer 68, and signal layer 67, insulated by first insulating layer 63, second insulating layer 64, third insulating layer 65, and fourth insulating layer 66. The electrical layers can be made of copper or other flexible conductive material. In one embodiment, the electrical layers can be one mil thick copper. Each electrical layer, and particularly signal layer 67, can be divided into a number of independent electrical paths. The electrical paths can be preformed and applied to the insulating layer, or can applied directly to the insulating layers by electroprinting, electrodeposition, or the like. The signal layer 67 has wire bond pads located at each chip site which are used to wire bond the copper circuit traces to each of the individual chips. In other embodiments, the order of the electrical layers can be varied as desired; for example, the power layer could be between the ground and signal layers. The insulating layers can be made of polyimide or other flexible insulating material. In one embodiment, the insulating layers can be two mil thick polyimide, such as Kapton® brand polyimide made by DuPont.

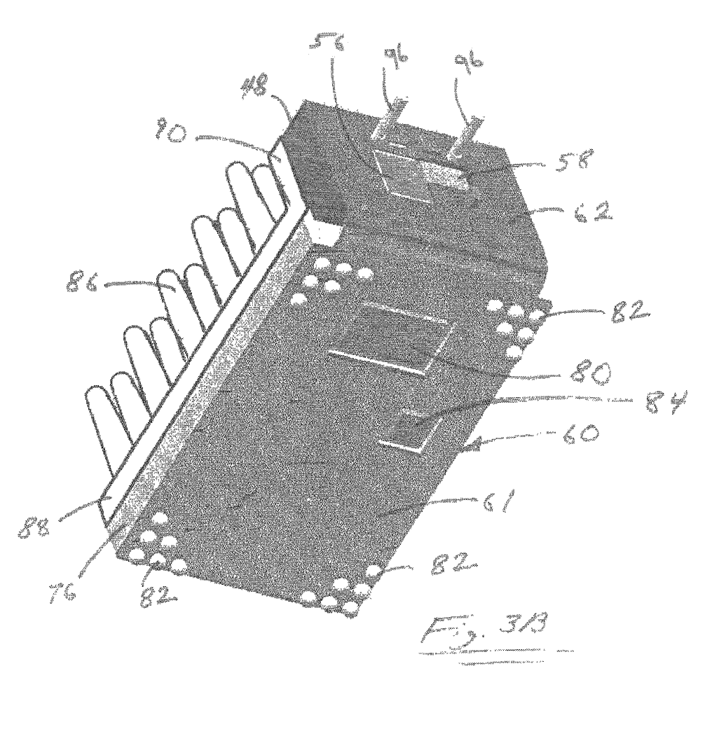

FIGS. 3A & 3B, in which like elements have like reference numbers, show isometric diagrams of a packaging architecture for a multiple array transceiver using a continuous flexible circuit made in accordance with the present invention. The flexible circuit has a plurality of layers to increase the data transfer capability between the forward vertical carrier and a rearward horizontal block.

The flexible circuit 60 has separate electrical paths connecting the rearward horizontal block 76 to the forward vertical carrier 48, where the laser die 52 and photodetector die 54 are located. Separate electrical paths can be provided for power, ground, and signal. Each electrical path can contain a plurality of conductors carrying a plurality of signals. The stacking of layers allows communication through a narrow gap, such as occurs between mounting screw locations specified by some industry and manufacturing standards. This allows the J-shaped interconnection between the rearward horizontal block 76 and forward vertical carrier 48 to carry a very large number of signals through a narrow horizontal gap.

The flexible circuit 60 can be attached to the rearward horizontal block 76 and the forward vertical carrier 48, which are attached to a heat sink 86. The second circuit portion 62 can be adhesively bonded to the face of the forward vertical carrier 48 where the electronic components are mounted. The first circuit portion 61 can be adhesively bonded to the bottom face of the rearward horizontal block 76. For ease of fabrication, the rearward horizontal block 76 and the forward vertical carrier 48 can both be laid on a flat surface, i.e., held in a single plane, during the initial assembly. The majority of the fabrication steps, including die bonding the electronic components to the blocks, attaching the flexible circuit to the blocks, wire bonding the electronic components to the flexible circuit, encapsulating the electronic components, and attaching a solder ball array, can be performed with the blocks on a flat surface. After those steps are completed, the assembly can be bent to form the 90-degree bend and the forward vertical carrier 48 attached to heat sink vertical portion 90 of heat sink 86 and rearward horizontal block 76 attached to heat sink horizontal portion 88 of heat sink 86.

The heat sink 86 incorporates a heat sink vertical portion 90 and a heat sink horizontal portion 88. The heat sink 86 can be made of a highly thermally conductive material, such as metal, and can be fabricated by die-casting, extrusion, and the like. The heat sink 86 provides the 90-degree angle between the forward vertical carrier 48 and the horizontal block 76, as well as heat transfer from those blocks. This 90-degree configuration is required due to the right angle orientation between the customer's interior circuit board and the rear bulkhead of the chassis. The heat sink 86 can have fins, pins, vanes, passive cooling, or active cooling on the open surface to assist in heat transfer.

The electronic components can be attached to the blocks by using standard die bond epoxy material and technique as will be appreciated by those skilled in the art. The flexible circuit 60 can have wire bond pads to provide the electrical connection between the electrical components and the flexible circuit.

The electronic components having the highest wiring density connection to the customer's interior board can be mounted in the horizontal block 76 closest to the solder ball array 82, which is used as the I/O interface and provides the connections to the customer's interior board. This location of such electronic components also reduces interconnect wiring density within the flexible circuit 60 in the direction of the electronic components on the forward vertical carrier 48, such as the laser 52, photodetector 54, LDA 56, and TIA 58 chips. In one embodiment, the EE PROM 80 and the Pdd postamplifier 84 chips can be mounted in the horizontal block 76. The horizontal block 76 can have cavities for electronic components, which allows EE PROM 80, Pdd postamplifier 84, and any other electronic components to sit below the soldering plane, thus providing physical clearance to allow use of the solder ball interconnection facing the customer's host board. In other embodiments, some of the electronic components above can be omitted from the horizontal block 76 and mounted elsewhere, or additional or alternative electronic components can be mounted on the horizontal block 76. The horizontal block 76 can be made of a material with good thermal conductivity, such as copper, aluminum nitride, or the like.

The heat sink 86 can further comprise a retainer shell to locate and hold a fiberoptic connector (not shown). The retainer housing is the female portion of the connector, which receives the customer's male end fiberoptic cable through the rear I/O bulkhead of the communications chassis and makes the connection to the multiple array transceiver. The forward vertical carrier 48 can provide locating pins 96 to align the multiple array transceiver optical path to the customer's fiberoptic cable. The locating pins 96 also establish a mechanical datum between the forward vertical carrier 48 and the retainer housing.

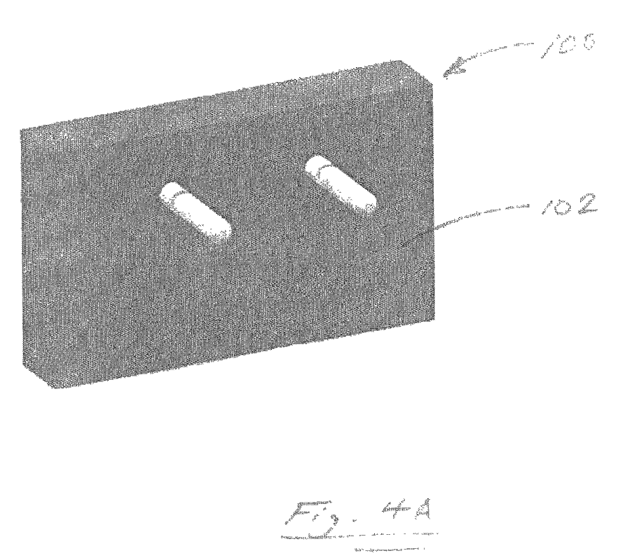

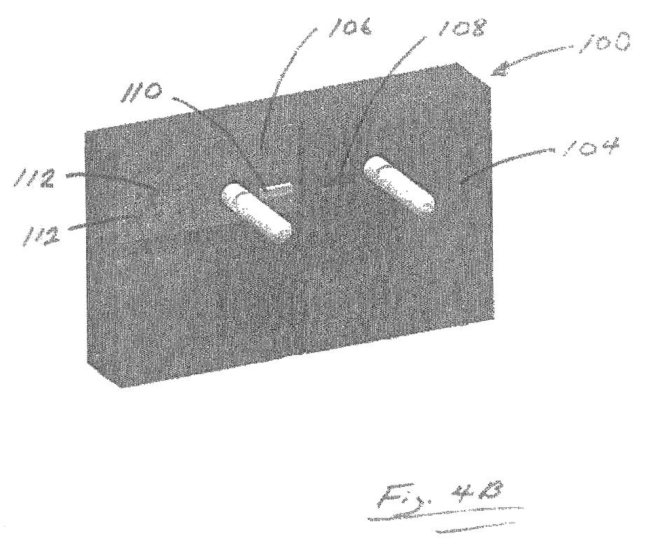

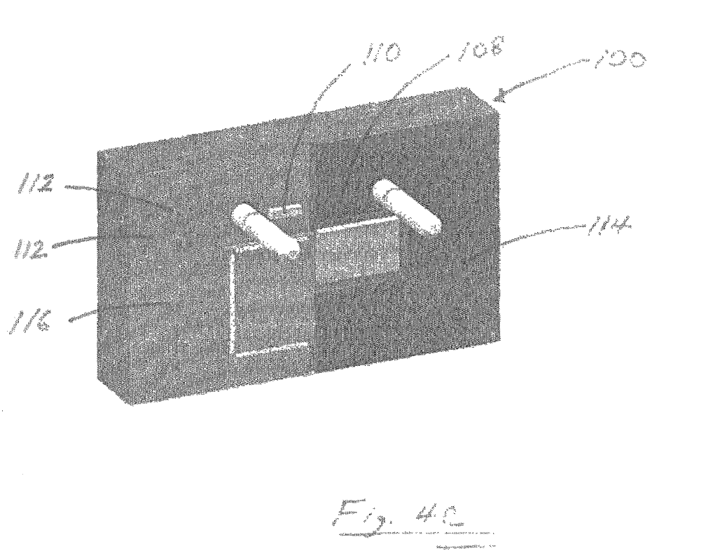

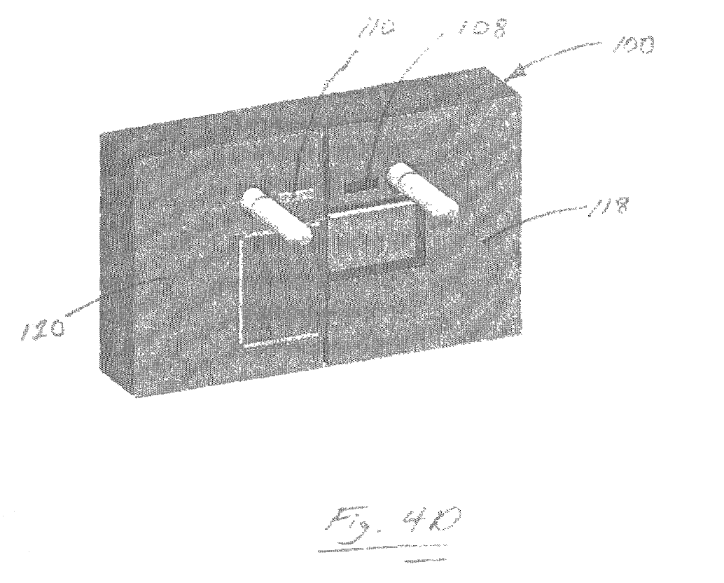

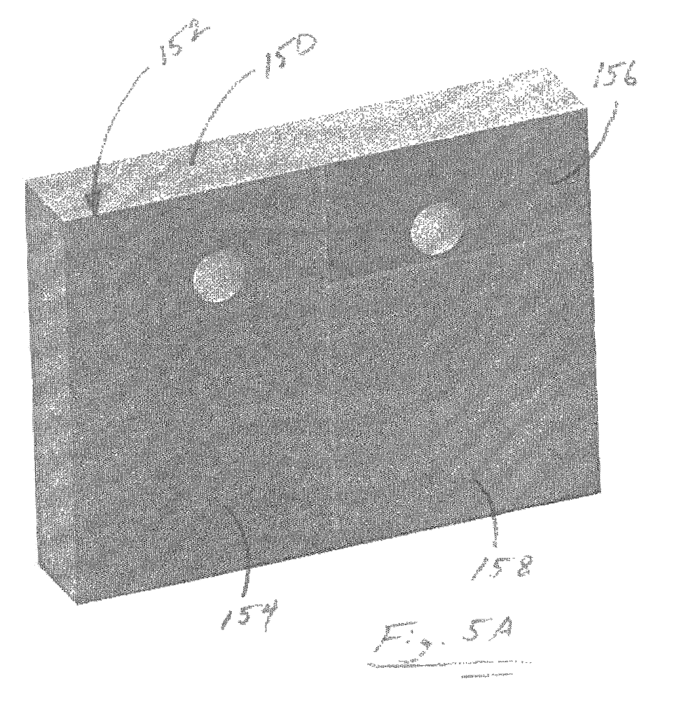

FIGS. 4A-4D, in which like elements have like reference numbers, show isometric diagrams of one embodiment of electrical connections for a forward vertical carrier made in accordance with the present invention. The embodiment allows connection of the different electrical components to the flexible circuit while maintaining coplanarity of the laser and photodetector chips.

Typical vertical cavity surface emitting laser die (VCSEL), such as those used for single and multiple optical transceiver array packages, use a common cathode. The cathode is physically located on the back plane of the laser chip die, opposite the circuit side. Typical photodetector die used for transceiver array packages use a common supply voltage located on the back plane of the photodetector chip die. Thus, the laser requires a ground at the back plane while the photodetector die requires supply voltage on the same plane.

This conflicts with the requirement that the emitting plane of the laser die and the receiving plane of the photodetector die both must lie in the same optical plane of reference, known as the Z plane. The need for Z plane die coplanarity arises regardless of whether the optical design uses a fiber optic coupler mounted nominally within 50-75 microns of the diverging laser light source to collect light into the fiber or uses a lens array mounted closely to both the laser and photodetector die to focus the laser light into the fiber. The embodiment illustrated in FIGS. 4A-4D discloses a method to attach both die to different layers of a flexible cable while maintaining coplanarity of the separate dies.

FIG. 4A shows a common substrate carrier 100 for a multiple array transceiver, having a component face 102. The common substrate carrier 100 can be made of a material with good thermal conductivity, such as copper, aluminum nitride, or the like. The component face 102 has a planar surface to create a common initial plane for mounting electrical components, particularly, to allow precise mounting of the optical components.

FIG. 4B shows the first layer applied to the component face of the common substrate carrier 100. The flexible circuit layer nearest the common substrate carrier 100 is typically the power layer. The first layer comprises first layer photodetector power 104 and first layer laser ground 106. The photodetector 108 can be die bonded to the first layer photodetector power 104 and the laser 110 can be die bonded to the first layer laser ground 106. This assures that the photodetector 108 and the laser 110 are coplanar. Vias 112 are holes in the insulation between layers and communicate between the first and second layers. When filled with conductive epoxy, the vias 112 provide connection between first layer laser ground 106 and the second layer.

FIG. 4C shows the second layer applied over the first layer. The flexible circuit layer second from the common substrate carrier 100 is typically the ground layer. The second layer comprises second layer photodetector ground 114 and second layer laser ground 116. The photodetector 108 and the laser 110 both pass through apertures in the second layer, but are not connected to the second layer. The vias 112 provide connection between the first layer laser ground 106 in the first layer and the second layer laser ground 116 in the second layer when filled with conductive epoxy.

FIG. 4D shows the third layer applied over the second layer. The flexible circuit layer third from the common substrate carrier 100 is typically the signal layer. The third layer comprises third layer photodetector signal 118 and third layer laser signal 120. The photodetector 108 and the laser 110 both pass through apertures in the third layer, but are not bonded to the third layer. Connections between the third layer and other electronic components, such as the TIA chip and LDA chip, can be made by wire bonding.

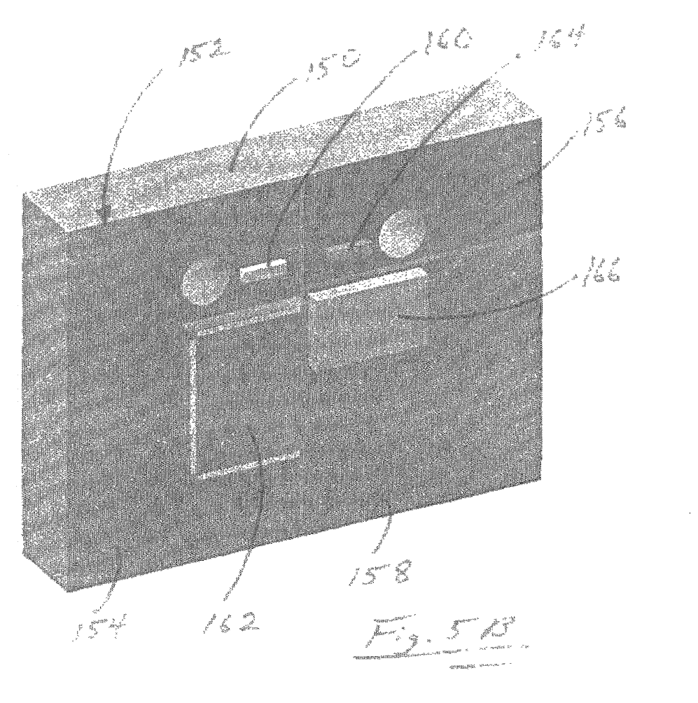

FIGS. 5A & 5B, in which like elements have like reference numbers, show isometric diagrams of another embodiment of electrical connections for a forward vertical carrier made in accordance with the present invention. The embodiment allows connection of the different electrical components to the common substrate carrier while maintaining short electrical path lengths. Multiple array transceivers typically operate at high frequencies of 2.5 GHz or higher, so the chipsets need to be in close proximity to decrease the electrical path lengths, reducing impedance and electrical cross talk. However, having the chipsets in close proximity can result in high heat density.

FIG. 5A shows a common substrate carrier 150 for a multiple array transceiver, having a component face 152. The common substrate carrier 150 can be made of a material with good thermal conductivity and good dielectric strength, such as aluminum nitride, or the like. The component face 152 is divided into three electrically isolated gold lands: laser and LDA ground reference land 154, photodetector voltage land 156, and TIA ground reference land 158. The component face 152 has a planar surface to create a common initial plane for mounting electrical components, particularly, to allow precise mounting of the optical components. This land arrangement meets the requirements of the particular electronic components, i.e., the laser, LDA, and TIA chips require a ground plane for attachment on the back, and the photodetector chip requires a voltage plane for attachment on the back. Separating the laser and LDA ground reference land 154 from the TIA ground reference land 158 prevents coupled noise at high frequencies. In one embodiment, the lands are made of gold sputtered or diffused onto the component face 152.

FIG. 5B shows electronic components mounted on the common substrate carrier 150. The laser die 160 and laser drive amplifier (LDA) chip 162 are attached to the laser and LDA ground reference land 154. The transimpedance amplifier (TIA) chip 166, used as a photodetector interface, is attached to the TIA ground reference land 158. The photodetector die 164 is attached to the photodetector voltage land 156. The connection between the die to the land can be made using standard electrically conductive epoxy used for die attachment, gold to gold-tin alloy reflow, or similar methods familiar to those skilled in the art. The primary heat removal path is through the thermally conductive common substrate carrier 150, because the component face 152 is insulated by the electronic components, flexible circuit attachments, and the fiberoptic connector.

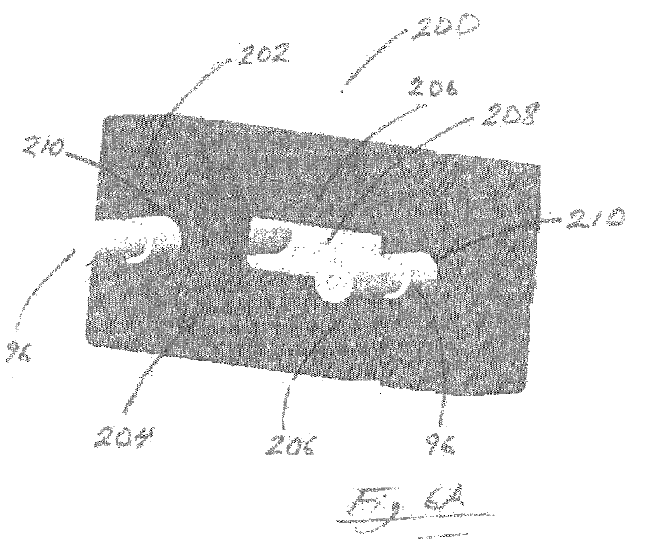

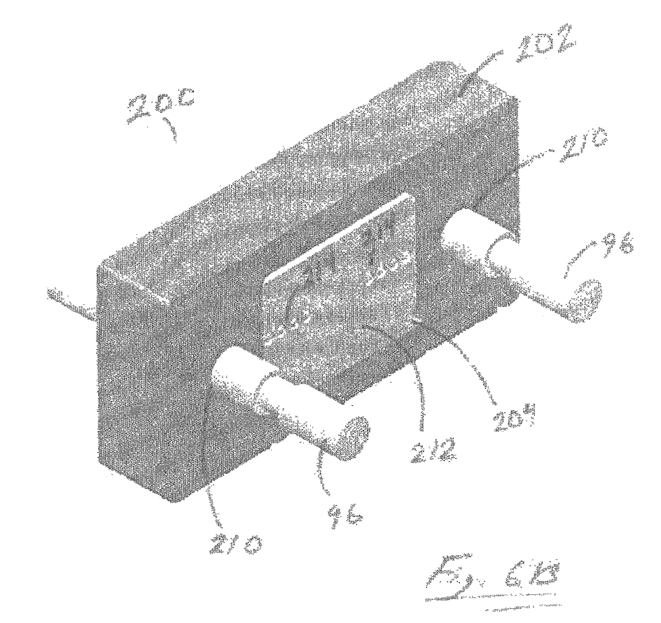

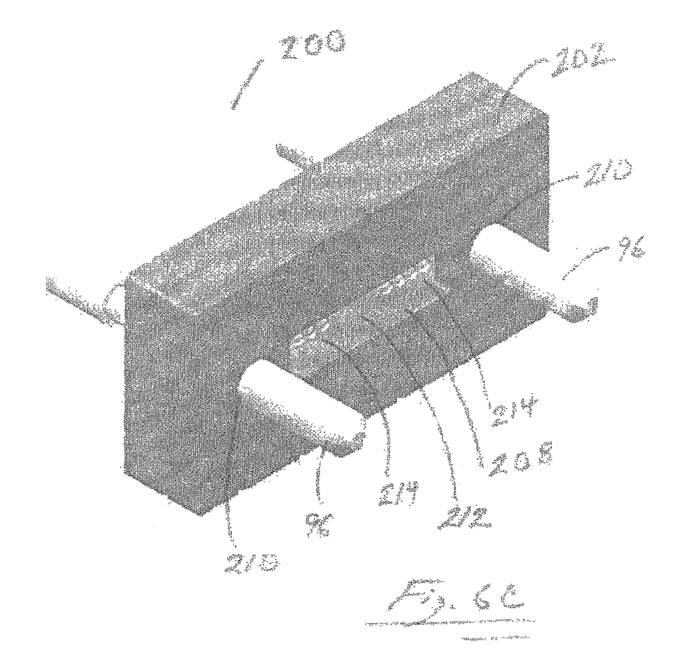

FIGS. 6A-6C, in which like elements have like reference numbers, show isometric diagrams of a multiple array transceiver lens assembly made in accordance with the present invention. The lens assembly can be used to couple the light signal to or from the multiple array transceiver to the external fiberoptic connector.

FIG. 6A shows a lens housing assembly 200 from the direction of the multiple array transceiver looking outward toward where the external fiberoptic connector would approach. The lens housing assembly 200 comprises a molded body 202 having a lens mounting aperture 204, parallel steps 206, lens aperture 208, and alignment pin apertures 210, shown with the alignment locating pins 96 in the alignment pin apertures 210. The optical lens array can be attached to the parallel steps 206 using a thin line adhesive. The alignment locating pins 96 are also shown in FIGS. 3A & 3B.

FIG. 6B shows a lens housing assembly 200 with the optical lens array 212 installed from the direction of the multiple array transceiver looking outward toward where the external fiberoptic connector would approach. The optical lens array 212 is disposed within the lens mounting aperture 204.

The optical lens array 212 can be made of a fused silica material that can be etched to create lens prescriptions in an array pattern, including symmetrical and asymmetrical lens designs. The optical lens array 212 can provide a plurality of lenses 214. The plurality of lenses 214 allows the lens housing assembly 200 to match the number of input and output optical signals at the multiple array transceiver. The optical lens array 212 enables higher coupling efficiency of light transfer through the ability of the optical lens array 212 to focus light divergence and convergence of the input and output optical signals.

The optical lens array 212 can be optically aligned using the alignment pin apertures 210 with the alignment locating pins 96 to establish the orientation between the optical lens array 212 and the molded body 202 as the optical lens array 212 is attached to the molded body 202. The alignment locating pins 96 are used during assembly to locate the lens housing assembly 200 relative to the laser and photodetector arrays of the forward vertical carrier. The alignment locating pins 96 also align the external cable fibers of the external fiberoptic connector with the optical lens array 212. The lens housing assembly 200 aligns all the optical elements in the optical path. The relative thicknesses of the molded body 202 and parallel steps 206 establish the proper dimensional distance to the respective image and focal planes of the optical lens array 212.

FIG. 6C shows a lens housing assembly 200 with the optical lens array 212 installed from the direction of the external fiberoptic connector looking inward toward the multiple array transceiver. The optical lens 212 is disposed within the lens mounting aperture 204. The plurality of lenses 214 is aligned with the lens aperture 208.

It is important to note that the figures and description illustrate specific applications and embodiments of the present invention, and is not intended to limit the scope of the present disclosure or claims to that which is presented therein. While the figures and description present a 2.5 gigahertz, 4 channel transmit and 4 channel receive multiple array transceiver, the present invention is not limited to that format, and is therefore applicable to other array formats including dedicated transceiver modules, dedicated receiver modules, and modules with different numbers of channels. Upon reading the specification and reviewing the drawings hereof, it will become immediately obvious to those skilled in the art that myriad other embodiments of the present invention are possible, and that such embodiments are contemplated and fall within the scope of the presently claimed invention.

While the embodiments of the invention disclosed herein are presently considered to be preferred, various changes and modifications can be made without departing from the spirit and scope of the invention. The scope of the invention is indicated in the appended claims, and all changes that come within the meaning and range of equivalents are intended to be embraced therein.

1. A packaging architecture system for a transceiver comprising:
a forward vertical carrier having an optical converter;
a rearward horizontal block, the rearward horizontal block oriented about 90 degrees from the forward vertical carrier; and
a flexible circuit operably connected between the forward vertical carrier and the rearward horizontal block, the flexible circuit having a plurality of electrical layers.

2. The system of claim 1 wherein the plurality of electrical layers further comprises a power layer, a ground layer, and a signal layer.

3. The system of claim 1 wherein the optical converter is at least one laser.

4. The system of claim 1 wherein the optical converter is at least one photodetector.

5. The system of claim 1 further comprising:
an electronic component die thermally connected to the forward vertical carrier.

6. The system of claim 1 further comprising:
an electronic component die thermally connected to the rearward horizontal block.

7. The system of claim 1 further comprising:
a heat sink having a heat sink vertical portion and a heat sink horizontal portion, the heat sink vertical portion being attached to the forward vertical carrier and the heat sink horizontal portion being attached to the rearward horizontal block.

8. The system of claim 1 wherein the forward vertical carrier has a component face, the component face having a ground land and a power land in the plane of the component face.

9. The system of claim 8 further comprising:
a laser die attached to the ground land and a photodetector die attached to the power land.

10. The system of claim 1 further comprising:
a lens housing assembly aligning an optical lens array with the optical converter.

11. A packaging architecture system for a transceiver comprising:
first means for supporting an optical converter;
second means for supporting an electrical connection, the second supporting means oriented about 90 degrees from the first supporting means; and
means for a electrically connecting the optical converter and the electrical connection, the electrical connecting means having a plurality of electrical layers.

12. The system of claim 11 wherein the plurality of electrical layers further comprises a power layer, a ground layer, and a signal layer.

13. The system of claim 11 wherein the optical converter is at least one laser.

14. The system of claim 11 wherein the optical converter is at least one photodetector.

15. The system of claim 11 further comprising:
an electronic component die thermally connected to the first supporting means.

16. The system of claim 11 further comprising:
an electronic component die thermally connected to the second supporting means.

17. The system of claim 11 further comprising:
means for removing heat thermally connected to the first supporting means and the second supporting means.

18. The system of claim 11 wherein the first supporting means has a component face, the component face having means for providing a ground and means for providing power, the ground providing means and the power providing means being located in the plane of the component face.

19. The system of claim 18 further comprising:
a laser die attached to the ground providing means and a photodetector die attached to the power providing means.

20. The system of claim 11 further comprising:
means for aligning a lens with the optical converter.

21. A packaging architecture system for a transceiver comprising:
a heat sink, the heat sink having a heat sink vertical portion and a heat sink horizontal portion, the heat sink vertical portion being oriented about 90 degrees from the heat sink horizontal portion;
a forward vertical carrier having an optical converter, the forward vertical carrier being attached to the heat sink vertical portion;
a rearward horizontal block, the rearward horizontal block being attached to the heat sink horizontal portion; and
a flexible circuit operably connected between the forward vertical carrier and the rearward horizontal block, the flexible circuit having a plurality of electrical layers.

22. The system of claim 21 wherein the plurality of electrical layers further comprises a power layer, a ground layer, and a signal layer

23. The system of claim 21 wherein the optical converter comprises at least one laser.

24. The system of claim 21 wherein the optical converter is at least one photodetector.
